(19) United States
(12) Patent Application Publication
(10) Pub. No.: US 2009/0002198 A1
(43) Pub. Date: Jan. 1, 2009

(54) Marine throttle mounted stereo control

(76) Inventor: Darren A. Bach, Tsawwassen (CA)

Correspondence Address: Darren A. Bach, 7993 Progress Way, Delta, BC, V4G 1A3, CA

(21) Appl. No.: 11/819,339

(22) Filed: Jun. 27, 2007

(51) Int. Cl. H03M 11/02; B65D 85/88; H01H 23/00; H04H 5/00; H01Q 1/44

(52) U.S. Cl. 341/20; 200/339; 206/703; 343/720; 381/3

(57) ABSTRACT

A marine throttle mounted stereo control system consisting of a throttle mounting base having a control shaft pivotally mounted to the mounting base, which is mounted adjacent an operators seat within a boat cockpit. The throttle control has a stereo control which is remotely located from the boats stereo audio system.

### TECHNICAL FIELD

The invention relates to a marine throttle mounted stereo control system, and more specifically to a stereo control system that is mounted on top of the throttle control for easy access by the operator to various stereo functions, including track changes and volume adjustments.

### BACKGROUND OF THE INVENTION

Modern sport boats have become more complex over the years as more functions are provided. Some of these functions include wakeboard towers and stereo audio equipment. These different functions are often used concurrently, with wakeboarders or skiers being towed as stereo audio is being played. Problems can arise for example when a skier tries to shout instructions to the operator. As quite often, the boats stereo system controls are mounted away from reach of the operator, causing miscommunication and potential dangerous consequences.

Inventor is aware of some remote stereo controls available, as well inventor is aware of U.S. Pat. No. 6,264,513 issued to Marsh on Jul. 24, 2001, entitled Wireless marine control system. Although this system solves some problems, it is designed for controlling multiple systems on a boat and consequently is too expensive for broad market appeal.

Accordingly, it is an object of the present invention to provide a marine throttle mounted stereo control system that improves boating safety.

Another object of the present invention is to provide a marine throttle mounted stereo control system, which is well suited for retrofitting to present marine throttle control.

A further object of the present invention is to provide a marine throttle mounted stereo control system that is convenient for the boat operator.

The marine throttle mounted stereo control system of the present invention has other objects and features of advantage which will become apparent from and are set forth in more detail in, the accompanying drawings and following details.

### DISCLOSURE OF THE INVENTION

The marine throttle mounted stereo control system of the present invention is designed to be retrofitted in place of an existing throttle control, and comprises briefly, a hand control knob, pivotally mounted onto a longitudinally extending shaft along the right side of the boat cockpit, adjacent the operators seat.

The preferred embodiment of the invention includes a control knob assembly with a circular rocker switch on the top area, where the rocker switch is operated by touch. The rocker switch is recessed below the top surface of the control knob for both easy access by feel and to prevent unintended activation of the stereo control.

The rocker switch may include various basic stereo control functions, which may include; a volume up and volume down control, a play and pause control and an audio track control, both a forward track and reverse track control. The audio track control may be either clicked quickly for track changes or held down for fast forward and fast reverse control within a song. As well the rocker switch may include another function, consisting of a central push button switch used to pause or play the stereo audio system. Or on the other hand, the various stereo functions could be reduced to simple volume up and volume down functions, depending on the boat manufactures desired functional options, or select variations of these mentioned functions.

The rocker switch can be a smooth circular plate which may include four visibly divided quadrants, which are activated by rocking in one of four directions, or the plate quadrants may be raised up for selection by feel, such as when the boat operator is preoccupied. In any case the switch uses micro switches situated under the rocker plate or under the centrally located play/pause button.

It should be noted that the control switch could achieve the same functionality if each function includes its own button or plate instead of that of a rocker switch, as with the centrally located play/pause button. This configuration would be a boat manufactures choice, or option and would not effect the operation, other than the finger would need slightly better placement when activating individual buttons.

In an alternate embodiment the stereo control switch is attached to the front, top area of the throttle control shaft, just below the throttle control knob. In this embodiment the function control is simplified to include only a volume up, volume down and possibly a mute control.

Depending on the boat manufactures choice, or option marine throttle mounted stereo control system of the present invention can be either hard wired or wireless controlled.

### BRIEF DESCRIPTION OF THE DRAWINGS

Advantages of the present invention will become more fully appreciated as the same becomes better understood when considered in conjunction with the following detailed description of an illustrative embodiment and accompanying drawings, in which like reference characters designate the same or similar parts throughout the several views, and wherein;

FIG. 1 is an elevated perspective view of the preferred embodiment of the invention.

FIG. 2 is a rear view of the preferred embodiment of the invention.

FIG. 3 is a top plan view of the preferred embodiment of the invention.

FIG. 4 is a side view of the preferred embodiment of the invention.

FIG. 5 is a close up segmental top plan view of the preferred embodiment of the invention.

FIG. 6 is a close up segmental perspective view of the preferred embodiment of the invention showing the stereo control embedded in the top of the throttle control knob.

FIG. 7 is an elevated perspective view of an alternate embodiment of the invention, showing the stereo control on the side of the throttle control knob.

FIG. 8 is an elevated perspective view of a second alternate embodiment of the invention, showing the stereo control on the front of the throttle control knob.

FIG. 9 is an elevated perspective view of a third alternate embodiment of the invention, showing a volume control switch on the shaft of throttle control.

### DETAILED DESCRIPTION OF THE PREFERRED EMBODIMENTS

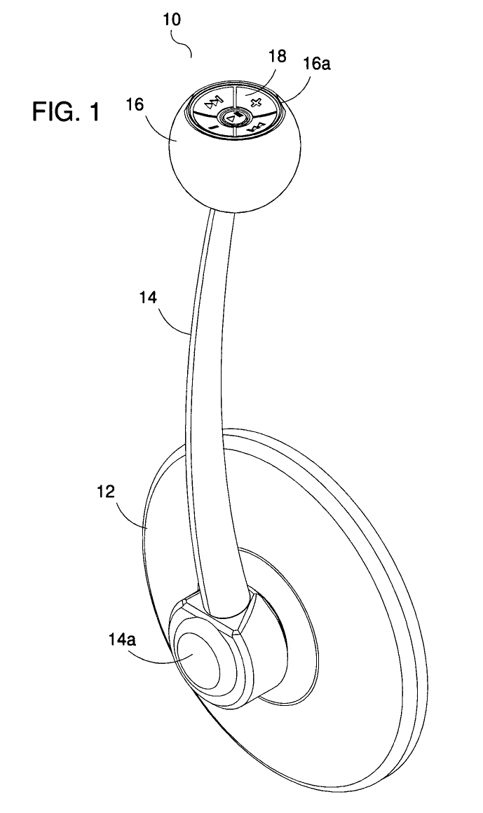

The marine throttle mounted stereo control system is generally referred to as 10 as shown in a perspective view in FIG. 1. Marine throttle mounted stereo control 10 has a throttle control mounting base 12, where throttle control mounting base 12 is normally mounted to the front right side of a cockpit area in a boat (not shown).

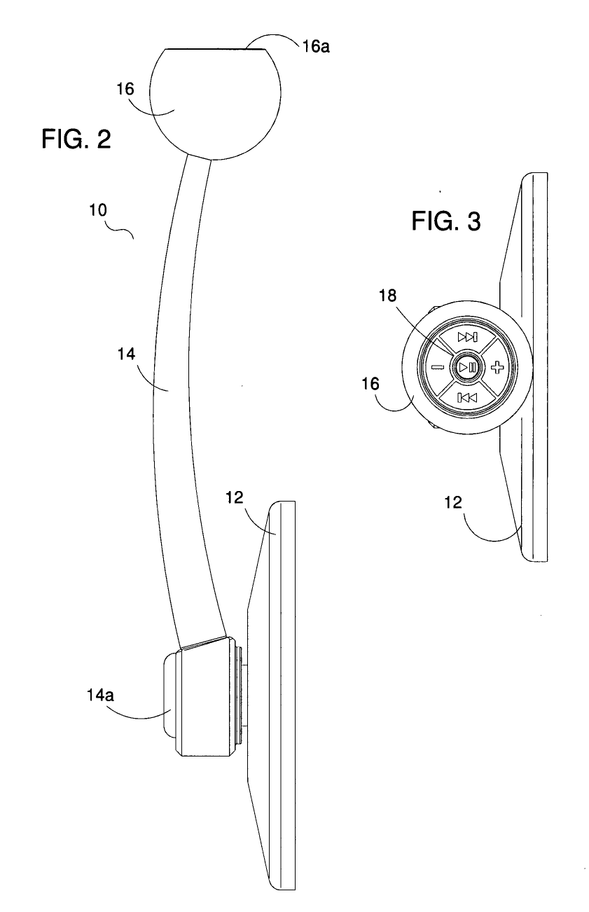

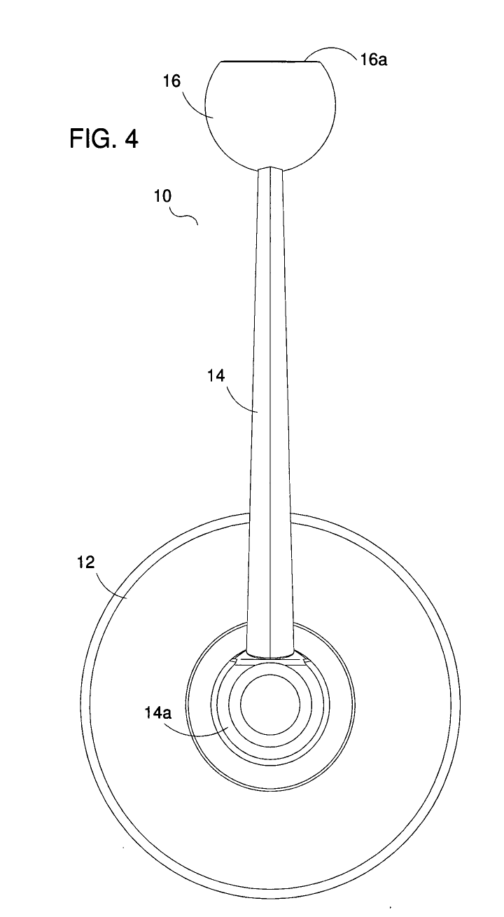

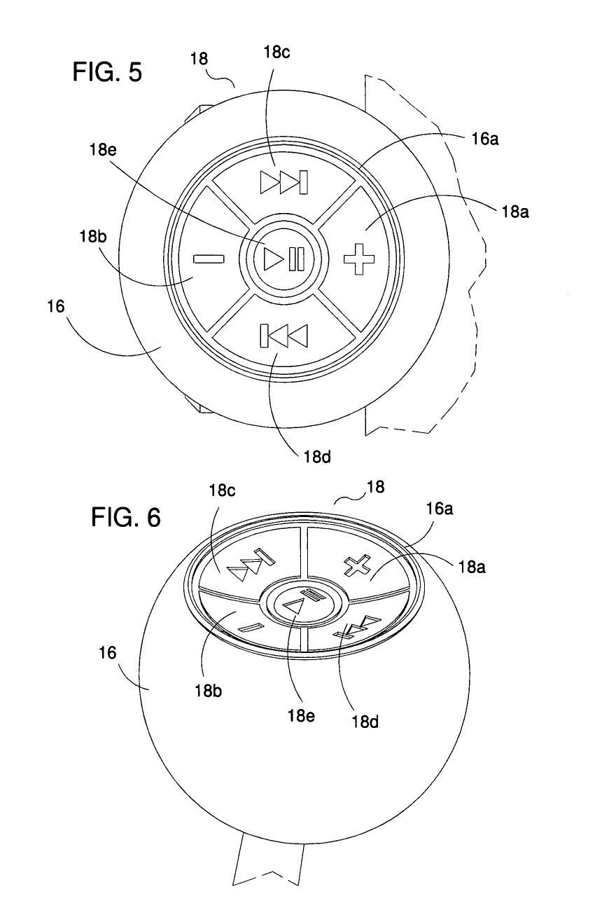

As best seen in FIGS. 2, 3 and 4 marine throttle mounted stereo control 10 includes a throttle control shaft 14 pivotally attached to mounting base 12 by control shaft connector 14a. Throttle control shaft 14 attaches a throttle control knob 16. Throttle control knob 16 includes a recessed area 16a. As best seen in FIG. 5 and FIG. 6 recessed area 16a includes a stereo control switch 18, where stereo control switch 18 includes a volume increase control 18a, a volume decrease control 18b, a track advance control 18c, a track reverse control 18d and a play and pause control 18e.

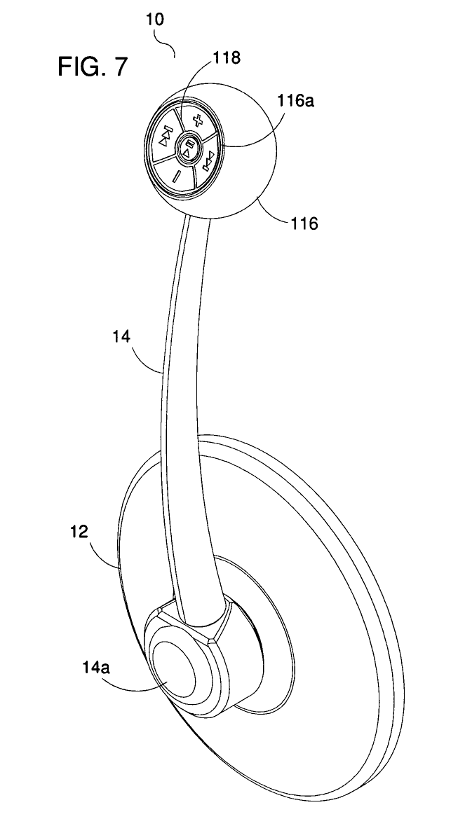

As seen in FIG. 7 stereo control 10 includes a throttle control shaft 14 pivotally attached to mounting base 12 by control shaft connector 14a. Throttle control shaft 14 attaches an alternate throttle control knob 116. Throttle control knob 116 includes a recessed area 116a.

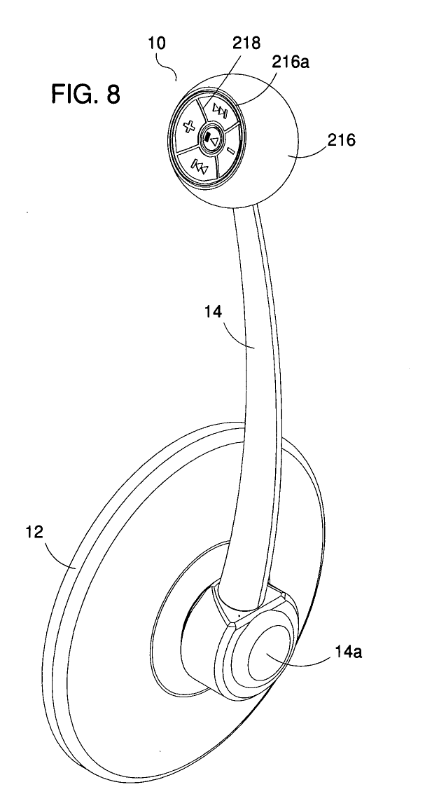

As seen in FIG. 8 stereo control 10 includes a throttle control shaft 14 pivotally attached to mounting base 12 by control shaft connector 14a. Throttle control shaft 14 attaches an second alternate throttle control knob 216. Throttle control knob 216 includes a recessed area 216a. Recessed area 216a includes a stereo control switch 218.

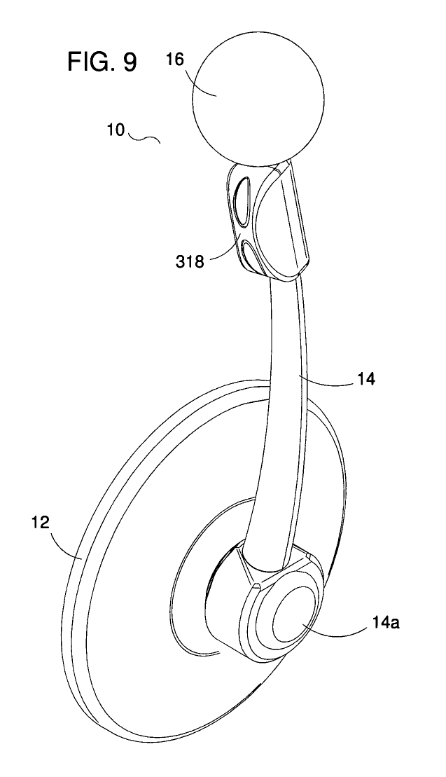

As seen in FIG. 9 stereo control 10 includes a throttle control shaft 14 pivotally attached to mounting base 12 by control shaft connector 14a. Throttle control shaft 14 attaches an alternate throttle stereo control switch 318.

The foregoing descriptions of specific embodiments of the present invention have been presented for purposes of illustration and description. They are not intended to be exhaustive or to limit the invention to the precise forms disclosed, and obviously many modifications and variations are possible in light of the above teaching. These modifications may include forming the base members separately and reversing male and female members. The embodiments were chosen and described in order to best explain the principles of the invention and its practical application, to thereby enable others skilled in the art to best utilize the invention and various embodiments with various modifications as are suited to the particular use contemplated.

It is intended that the scope of the invention be defined by the Claims appended hereto and their equivalents.

What is claimed is:

1. A marine throttle mounted stereo control system, where said marine throttle includes a mounting base having a control shaft pivotally mounted to said mounting base, where said mounting base is mounted adjacent an operators seat within a cockpit mounted to a boat; wherein said throttle control shaft includes a knob mounted on top of said throttle control shaft; where said stereo control is mounted to said knob; and where said stereo control is remote to stereo audio system.

2. The marine throttle mounted stereo control system of claim 1 wherein said stereo control includes a rocker switch.

3. The marine throttle mounted stereo control system of claim 2 where said rocker switch is mounted within a recessed area of said knob.

4. The marine throttle mounted stereo control system of claim 2 wherein said rocker switch is a four quadrantal rocker switch.

5. The marine throttle mounted stereo control system of claim 4 wherein said quadrantal rocker switch includes visibly divided marked quadrants.

6. The marine throttle mounted stereo control system of claim 4 wherein said quadrantal rocker switch includes visibly divided raised quadrants.

7. The marine throttle mounted stereo control system of claim 4 wherein said quadrantal rocker switch includes a centrally located control button.

8. The marine throttle mounted stereo control system of claim 1 wherein said stereo control functions includes a volume control.

9. The marine throttle mounted stereo control system of claim 1 wherein said stereo control functions includes an audio track control.

10. The marine throttle mounted stereo control system of claim 1 wherein said stereo control functions as a pause/play button.

11. The marine throttle mounted stereo control system of claim 1 wherein said stereo control is hard wired.

12. The marine throttle mounted stereo control system of claim 1 wherein said stereo control is wireless.

13. A marine throttle mounted stereo control system, where said marine throttle includes a mounting base having a control shaft pivotally mounted to said mounting base, where said mounting base is mounted adjacent an operators seat within a cockpit mounted to a boat; wherein said throttle control shaft includes a stereo control switch; and where said stereo control switch is remote to stereo audio system.

14. The marine throttle mounted stereo control system of claim 13 wherein said stereo control switch is hard wired.

15. The marine throttle mounted stereo control system of claim 13 wherein said stereo control switch is wireless.

16. A marine throttle mounted stereo system, where said marine throttle includes a mounting base having a control shaft pivotally mounted to said mounting base, where said mounting base is mounted adjacent an operators seat within a cockpit mounted to a boat; wherein said throttle control shaft includes a knob mounted on top of said throttle control shaft where said knob is a stereo audio system; and where said stereo audio system comprises a miniature stereo MP3 player having FM radio transmissions.

17. The marine throttle mounted stereo system of claim 16 wherein said stereo audio system is controlled by a recessed multi switch.

18. The marine throttle mounted stereo system of claim 16 wherein said stereo audio system uses said shaft as an FM transmitting antenna.

19. The marine throttle mounted stereo system of claim 16 wherein said stereo control uses said shaft for storage of batteries for said stereo audio system.

20. The marine throttle mounted stereo system of claim 16 wherein said stereo audio system is hardwired.
